(19) United States
(12) Patent Application Publication
(10) Pub. No.: US 2005/0074197 A1
(43) Pub. Date: Apr. 7, 2005

(54) Integrated surface emitting laser and light amplifier

(75) Inventors: Hitoshi Tada, Tokyo (JP); Keisuke Matsumoto, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/638,389

(22) Filed: Aug. 12, 2003

(30) Foreign Application Priority Data
Mar. 11, 2003 (JP) 2003-064902

(51) Int. Cl. G02B 6/12; H01S 5/20

(52) U.S. Cl. 385/14; 372/50; 359/344

(57) ABSTRACT

An integrated surface emitting laser and light amplifier element having a high power output, and a large variable wavelength includes a surface light emitting laser having an active layer between two reflection films facing each other and a light amplifier including an amplifying active layer for amplifying a laser beam produced by the surface light emitting laser. The surface light emitting laser and the light amplifier are integrated on the same substrate.

### BACKGROUND OF THE INVENTION

1. Field of the Invention

The present invention relates to a light amplifier integrated surface emitting laser element, in which a surface light emitting laser and a light amplifier are integrated with each other and, more particularly, relates to a light amplifier integrated surface emitting laser element, in which a wavelength variable surface light emitting laser and a light amplifier are integrated with each other.

2. Description of the Related Art

In a large capacity optical communication system using an optical fiber, there has been widely used a WDM (i.e., wavelength division multiplexing) transmission system, in which several tens of signal optical fluxes different in wavelength at a certain fixed interval are bundled together. Since one optical fiber can transmit signals of several wavelengths in this system, a transmission capacity can be increased without additionally providing any optical fiber. It is necessary to form the oscillation wavelength of a semiconductor laser for sending a signal with remarkably high accuracy in the WDM transmission system, and therefore, a method for controlling the temperature of a DBF laser has been generally used. In the DBF laser, a diffraction grating is formed adjacently to an active layer, and an arbitrary wavelength can be obtained by adjusting the pitch of the diffraction grating. Furthermore, the oscillation wavelength is varied at a rate of about 0.1 nm/° C. in the DBF laser, and therefore, the oscillation wavelength can accurately accord with a wavelength required for the WDM transmission.

In the WDM transmission system, a plurality of wavelengths (for example, 32 to 64 wavelengths) are selected within a wide range of 1528 nm to 1565 nm. In order to prepare DBF lasers different in wavelength, it is necessary to fabricate diffraction gratings according to the wavelengths per wafer. Furthermore, in order to prepare lasers by the number of required wavelengths, it is necessary to fabricate wafers corresponding to the number of required wavelengths. Moreover, in the case where several lasers of a certain wavelength are required, lasers are fabricated per wafer (several thousands of wafers), thereby markedly increasing a cost and deteriorating efficiency.

In order to solve the above-described problems, attention has been directed toward wavelength variable lasers, in which a single element can cover several wavelengths. Among such wavelength variable lasers, a surface light emitting type wavelength variable laser is featured in that a wavelength can be instantaneously varied by varying the length of a laser resonator, and further, that the width of a variable wavelength can be enlarged. Therefore, study has been earnestly carried out. For example, Non Patent Literature discloses an example in which an MEMS and a surface light emitting laser are integrated with each other.

Additionally, Patent Literature 1 discloses a wavelength division multiplexing transmission system using a surface light emitting laser having a movable reflection mirror and, more particularly, a wavelength variable laser diode in which an optical element consisting of a mirror and a waveguide is formed at the upper surface of the laser (see FIG. 9 and Paragraph No. 0073).

[Patent Literature 1]

Japanese Non-examined Patent Publication No. 2002-289,969

[Non Patent Literature 1]

International Conference on Indium Phosphide and Related Materials Conference Proceeding TuAl-2, C. J. Chang-Hasnain, 2001

However, although an optical output of 5 mW to 10 mW or more is generally required for a laser for use in optical fiber communications, it is difficult to increase an optical output in the surface light emitting laser since the volume of an active layer is small from the viewpoint of its structure, thereby arising a problem of an optical output as small as about 1 mW.

No means for solving the above-described problem is. disclosed even in Patent Literature 1.

### SUMMARY OF THE INVENTION

An object of the present invention is to provide a light amplifier integrated surface emitting laser element of a high output, having a great wavelength variable width.

In order to achieve the above-described object, a light amplifier integrated surface emitting laser element according to the present invention comprises a surface light emitting laser having an active layer between two reflection films facing to each other and a light amplifier including an amplifying active layer for amplifying a laser beam oscillated by the surface light emitting laser, the surface light emitting laser and the light amplifier are provided integrally with each other on one and the same substrate.

### BRIEF DESCRIPTION OF THE DRAWINGS

FIG. 1 is a perspective view showing a light amplifier integrated surface emitting laser element in a first embodiment according to the present invention;

FIG. 2 is a cross-sectional view taken along a line A-A′ of FIG. 1;

FIG. 3 is a perspective view showing the light amplifier integrated surface emitting laser element after a first step in a fabricating process in the first embodiment according to the present invention;

FIG. 4 is a perspective view showing the light amplifier integrated surface emitting laser element after a second step in the fabricating process in the first embodiment according to the present invention;

FIG. 5 is a perspective view showing the light amplifier integrated surface emitting laser element after a third step in the fabricating process in the first embodiment according to the present invention;

FIG. 6 is a perspective view showing the light amplifier integrated surface emitting laser element after a fourth step in the fabricating process in the first embodiment according to the present invention;

FIG. 7 is a perspective view showing the light amplifier integrated surface emitting laser element after a fifth step in the fabricating process in the first embodiment according to the present invention;

FIG. 8 is a perspective view showing the light amplifier integrated surface emitting laser element after a sixth step in the fabricating process in the first embodiment according to the present invention;

FIG. 9 is a perspective view showing the light amplifier integrated surface emitting laser element after a seventh step in the fabricating process in the first embodiment according to the present invention;

FIG. 10 is a perspective view showing the light amplifier integrated surface emitting laser element after an eighth step in the fabricating process in the first embodiment according to the present invention;

FIG. 11 is a perspective view showing a light amplifier integrated surface emitting laser element in a second embodiment according to the present invention; and

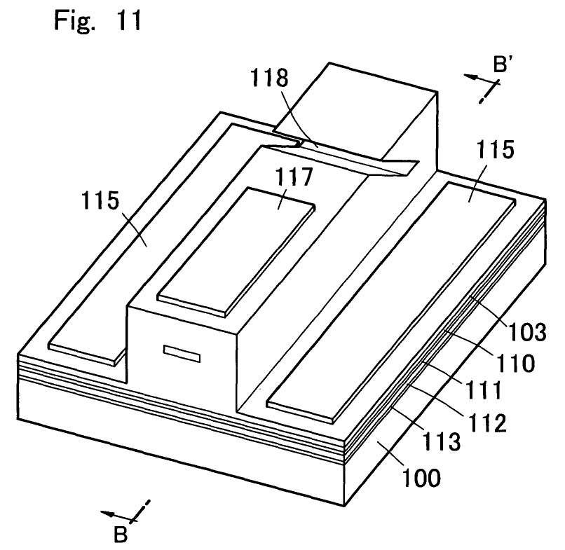

FIG. 12 is a cross-sectional view taken along a line B-B′ of FIG. 11.

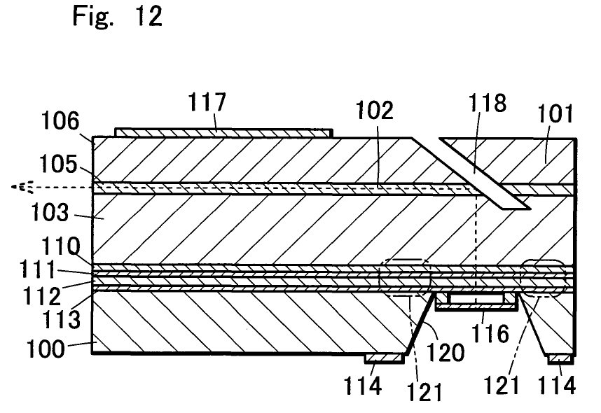

### DESCRIPTION OF THE PREFERRED EMBODIMENTS

Light amplifier integrated type surface light emitting laser elements in embodiments according to the present invention will be described below in reference to the accompanying drawings.

### First Embodiment

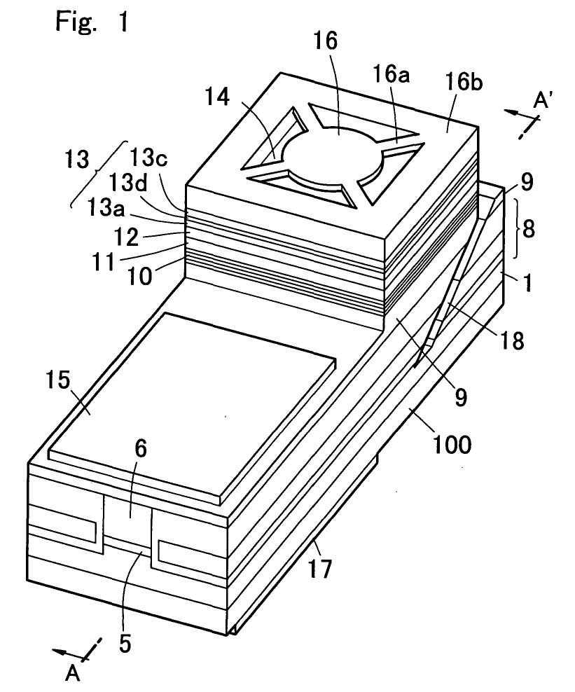

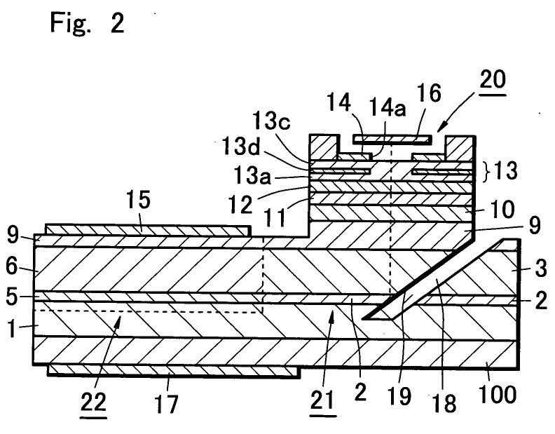

As shown in FIGS. 1 and 2, a light amplifier integrated surface emitting laser element in a first embodiment according to the present invention is featured in that a surface light emitting laser 20, a light amplifier 22, and an optical waveguide 21 for connecting the surface light emitting laser and the light amplifier to each other are monolithically integrated on a single substrate 100. In this manner, the light amplifier integrated surface emitting laser element is configured such that an output is high and a variable wavelength range is wide.

Specifically, in the light amplifier integrated surface emitting laser element in the first embodiment, a first cladding layer 1 (which is made of, for example, p-type InP), a waveguide layer 2 (which is made of, for example, undoped InGaAsP) and a second cladding layer 3 (which is made of, for example, n-type InP) are laminated in sequence at a part (i.e., a first region) of the upper surface of the substrate 100 (which is made of, for example, p-type InP), thereby constituting the optical waveguide 21, as shown in FIGS. 1 and 2.

Incidentally, each of the second cladding layer 3 and the waveguide layer 2 is narrowly formed in such a manner as to be sufficiently reduced in width (for example, 1.5 μm) in comparison with the length in a longitudinal direction, and further, current blocking layers 8 (for example, having a three-layer structure of p-type InP/n-type InP/p-type InP) are embedded and grown on both sides of the second cladding layer 3 and the waveguide layer 2.

With this constitution, the optical waveguide 21 can guide a laser beam in the longitudinal direction of the waveguide layer 2.

The surface light emitting laser 20 includes a contact layer 9 (which is made of, for example, n-type InP), which is shared by the light amplifier 22. The surface light emitting laser 20 comprises: a semiconductor laminate, in which a first reflection film 10 (in which, for example, n-type InP layers and n-type InGaAsP layers are alternately laminated), a first cladding layer 11 in the laser (which is made of, for example, an n-type InP layer), an active layer 12 (which has, for example, an undoped InGaAsP/InGaAsP multiple quantum well structure) and a second cladding layer 13 in the laser (which has a three-layer structure consisting of, for example, a p-type InP layer/a p-type AlInAs layer/a p-type InP layer) are laminated in the above-described order on the contact layer 9; and an anode electrode 14 and a second reflection film 16 (which are made of, for example, an SiO₂/TiO₂ multiple film) formed on the semiconductor laminate. Here, the second reflection film 16 is movably supported by four beam portions 16a apart from the upper surface of the semiconductor laminate. A clearance between the second reflection film 16 and the semiconductor laminate is adjusted by electrostatic force corresponding to a voltage to be applied to a reflection film movement control electrode (not shown). Consequently, it is possible to vary a resonator clearance between the first reflection film and the second reflection film, thereby varying a laser oscillation wavelength according to the resonator clearance.

Incidentally, one end of each of the beam portions 16a is connected to the second reflection film 16; in the meantime, the other end of each of the beam portions 16a is connected to a fixing portion 16b formed at the outer peripheral portion of the semiconductor laminate.

Furthermore, another electrode for exciting the surface light emitting laser is a cathode electrode 15 shared by the light amplifier 22.

Moreover, the surface light emitting laser 20 and the optical waveguide 21 are arranged such that the optical axis of the surface light emitting laser 20 is aligned with that of the optical waveguide 21.

In the light amplifier integrated surface emitting laser element in the first embodiment, the first cladding layer 1 (which is made of, for example, p-type InP), a light amplifying active layer 5 (which is made of, for example, undoped InGaAsP) and another second cladding layer 6 (which is made of, for example, n-type InP) are laminated in sequence in a second region at the upper surface of the substrate 100, thereby constituting the optical waveguide. The optical waveguide is held between the cathode electrode 15 and another anode electrode 17 via the contact layer 9 and the substrate 100, thus configuring the light amplifier 22.

The widths of the second cladding layer 6 and the light amplifying active layer 5 are set equally to those of the waveguide layer and the second cladding layer 3 in the optical waveguide, respectively.

Moreover, the optical waveguide 21 and the light amplifier 22 are arranged such that their optical axes are aligned with each other.

The above-described light amplifier integrated surface emitting laser element in the first embodiment is provided with the movable second reflection film, wherein the laser oscillation wavelength can be varied by varying the resonator clearance, thus relatively enlarging the wavelength variable range.

Furthermore, since the surface light emitting laser 20, the optical waveguide 21 and the light amplifier 22 are monolithically integrated on the single substrate 100 in the above-described positional relationship, a laser beam oscillated by the surface light emitting laser 20 can be output after the amplification by the light amplifier 22, thereby achieving the laser beam of a high output.

Method for Fabricating Light Amplifier Integrated Type Surface

### Light Emitting Laser Element in First Embodiment

Referring to the accompanying drawings, explanation will be made on a method for fabricating the light amplifier integrated surface emitting laser element in the first embodiment according to the present invention.

Although materials and dimensions are specifically illustrated in the explanation below made on the fabricating method, the present invention is not limited to such materials and dimensions.

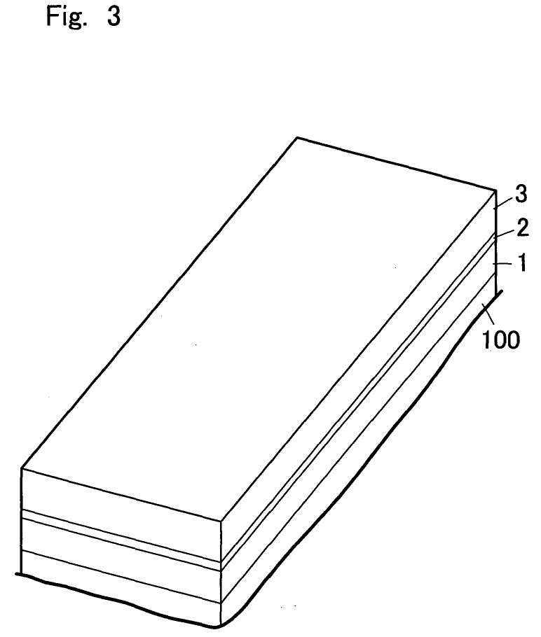

In the present fabricating method, first, the p-type InP cladding layer 1 (i.e., the first cladding layer 1), the undoped InGaAsP waveguide layer 2 (i.e., the waveguide layer 2) and the n-type InP cladding layer 3 (i.e., the second cladding layer 3) are grown on the p-type InP substrate 100 by organic metal vapor phase epitaxy (see FIG. 3). These three layers are layers constituting the optical waveguide 21. Here, the composition of the undoped InGaAsP waveguide layer 2 is set such that a photoluminescence wavelength becomes 1.3 μm.

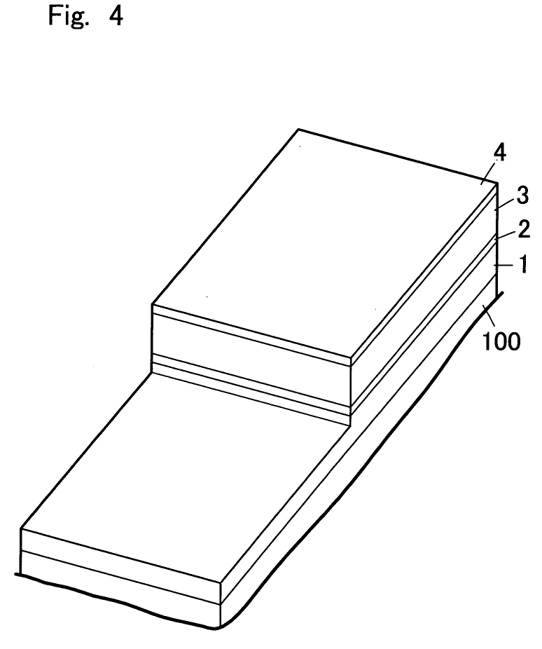

Subsequently, an SiO₂ insulating film 4 is formed at a part of the n-type InP cladding layer 3 (i.e., a portion having a predetermined length from one end and corresponding to the first region); in the meantime, the n-type InP cladding layer 3 and the undoped InGaAsP waveguide layer 2 at a portion having no SiO₂ insulating film 4 formed thereon are removed by etching (see FIG. 4).

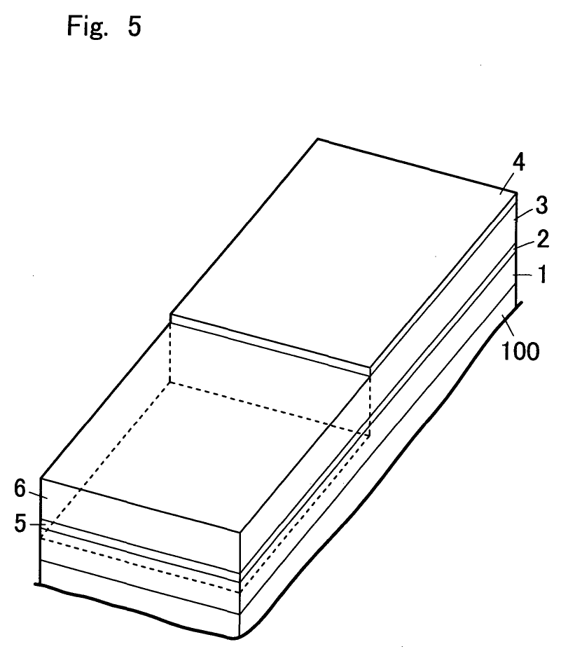

And then, the undoped InGaAsP active layer 5 (i.e., the light amplifying active layer 5) and the n-type InP cladding layer 6 (i.e., the second cladding layer 6) are grown on the p-type InP cladding layer 1 (corresponding to the second region), which has been removed by etching and exposed by the use of the SiO₂ insulating film 4 as a selective growth mask, by organic metal vapor phase epitaxy (see FIG. 5). Here, the composition of the undoped InGaAsP active layer 5 is set such that a photoluminescence wavelength becomes 1.55 μm.

After the selective growth, the SiO₂ insulating film 4 is removed with a fluoric acid solution.

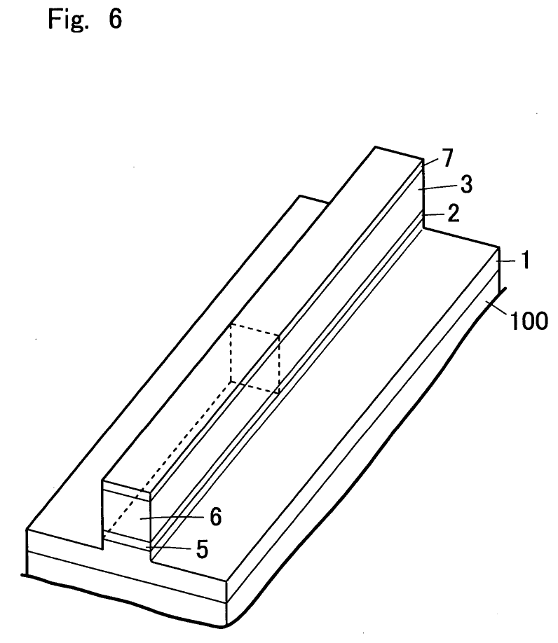

Subsequently, an SiO₂ mask 7 having a width of 2 μm is formed on the n-type InP cladding layer 3 and the n-type InP cladding layer 6, and then, a mesa having a depth of 2 μm is formed by dry etching using gaseous CH₄/H₂ (see FIG. 6).

Through the above-described processes, the optical waveguide and the light amplifier can be provided in connection to each other with the remarkably reduced misalignment of the optical axes.

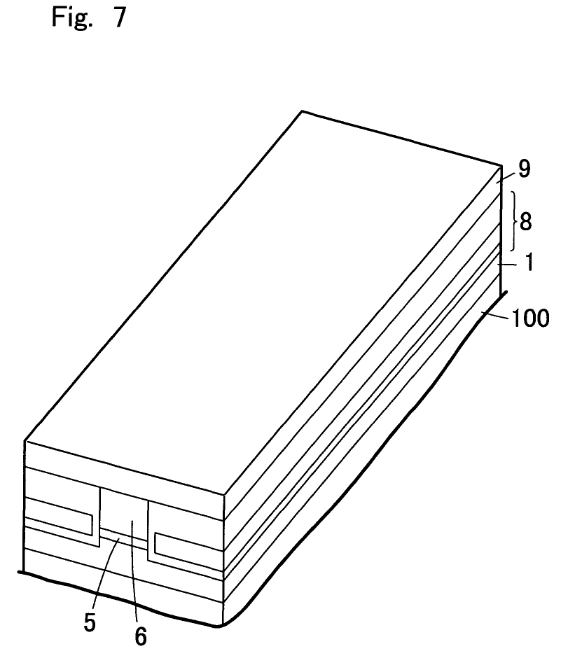

After the mesa is formed, the current blocking layers 8 of p-type InP/n-type InP/ p-type InP are embedded and grown on both sides of the mesa by using the SiO₂ mask 7 as the selective growth mask, and then, the SiO₂ mask 7 is removed, so that the n-type InP contact layer 9 is formed over the entire surface (see FIG. 7).

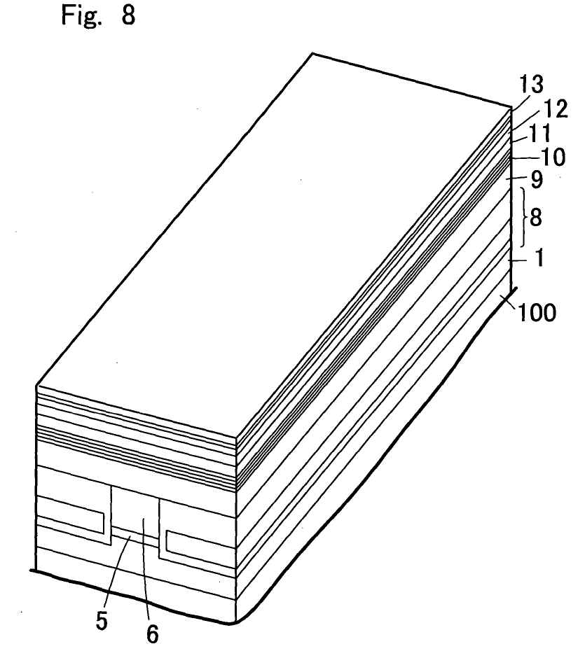

Next, the multi-layer reflection film 10 consisting of the n-type InP layer/n-type InGaAsP layer, the n-type InP cladding layer 11, the undoped InGaAsP/InGaAsP multiple quantum well active layer 12, a p-InP layer 13a, a p-AlInAs current narrowing layer 13b and another p-InP layer 13c are grown on the n-type InP contact layer 9 (see FIG. 8).

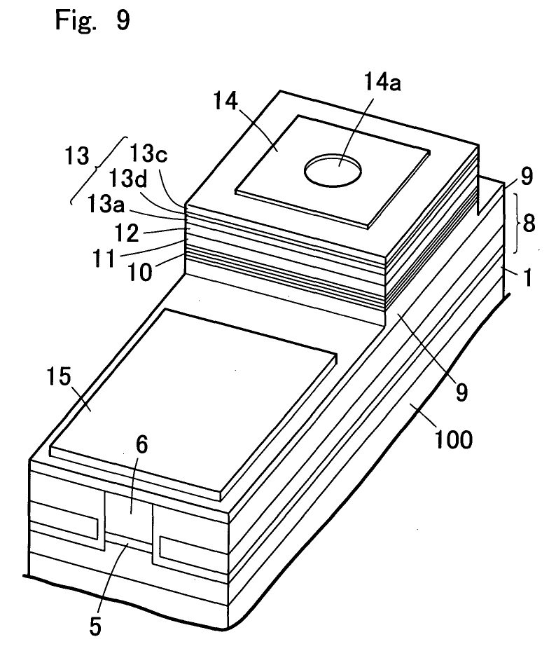

While a surface light emitting laser oscillator remains, etching is carried out down to the undoped InGaAsP/InGaAsP multiple quantum well active layer 12 (that is, until the n-type InP contact layer 9 is exposed), thereby forming the semiconductor laminate for constituting the laser element. The cathode electrode 15 is formed on the n-type InP contact layer 9 exposed by forming the anode electrode 14 at the upper surface of the laminate. Here, a circular opening 14a is formed at the center of the anode electrode 14 (see FIG. 9).

Incidentally, after the formation of the semiconductor laminate, the AlInAs layer 13b in the second cladding layer 13 in the laser is oxidized in a lateral direction, thereby forming a high resistance layer 13d for blocking a current.

Subsequently, the SiO₂/TiO₂ multiple reflection film 16, for example, is formed on the p-type InP cladding layer with an air gap of 0.2 μm to 0.3 μm.

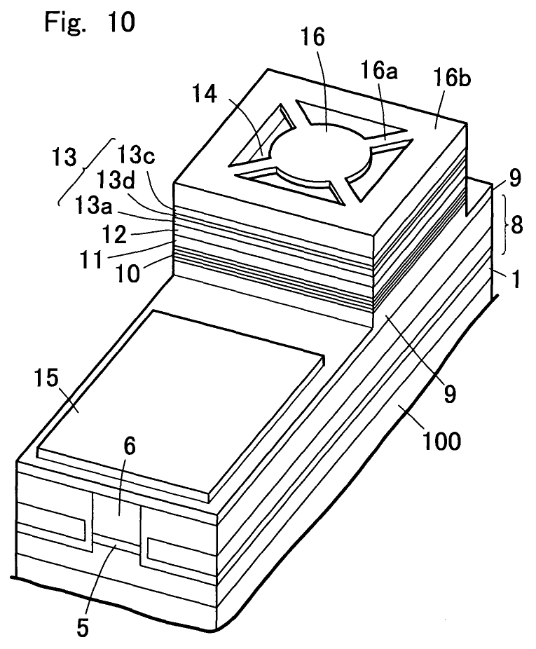

Specifically, a sacrifice layer, which can be removed by etching, is formed on the semiconductor laminate, and then, the SiO₂/TiO₂ multiple reflection film 16, the beam portions 16a for supporting the SiO₂/Ti₂ multiple reflection film 16 and the fixing portions 16b for fixing the beam portions 16a are formed integrally with each other. Thereafter, the SiO₂/TiO₂ multiple reflection film 16 having a hollow (movable) structure is formed by removing only the sacrifice layer (see FIG. 10). At this time, the SiO₂/TiO₂ multiple reflection film 16 and the beam portions 16a for supporting the SiO₂/TiO₂ multiple reflection film 16 are formed on the sacrifice layer; in the meantime, the fixing portions 16b are formed in direct contact on the cladding layer 13. Here, the SiO₂/TiO₂ multiple reflection film 16 is designed to have a reflectivity of 99% or higher.

Although a process of fabricating an electrode film for controlling the movement of the SiO₂/TiO₂ multiple reflection film 16 is omitted in the above description, an electrode film for controlling the movement is formed at either of the upper and lower surfaces of the SiO₂/TiO₂ multiple reflection film 16.

After the surface light emitting laser 20 and the optical waveguide 21 are formed in the above-described manner, a groove 18 is formed at an angle of 45° with respect to each of the optical axes of the surface light emitting laser 20 and the optical waveguide 21 at a portion at which the optical axis of the surface light emitting laser 20 is perpendicular to that of the optical waveguide 21, thereby forming a reflection mirror 19 for reflecting the laser beam in the advance direction of the optical waveguide (see FIGS. 1 and 2).

Since the groove 18 can be formed by, for example, dry etching using an Ar ion in an inclined state of wafer at an angle of 45°, the reflection mirror 19 can be easily formed.

After the formation of the groove 18, the substrate 100 is polished in a thickness of 100 μm, and thereafter, the anode electrode 17 for the light amplifier is formed at a position facing to the cathode electrode 15 at the reverse of the substrate 100.

Through the above-described processes, the light amplifier integrated surface emitting laser element in the first embodiment is fabricated.

In the above-described method for fabricating the light amplifier integrated surface emitting laser element in the first embodiment, the surface light emitting laser 20, the optical waveguide 21, the light amplifier 22 and the reflection mirror 19 can be formed integrally with each other by using a so-called semiconductor fabricating technique, so that it is possible to readily align the optical axes with each other with high accuracy. Thus, it is possible to fabricate the light amplifier integrated surface emitting laser element of the remarkably high output, having the great variable wavelength width.

In the light amplifier integrated surface emitting laser element in the first embodiment, the length of the resonator (i.e., the interval between the first reflection film 10 and the second reflection film 16) is set to 3 μm; the undoped InGaAsP/InGaAsP multiple quantum well active layer 12 is designed to have the composition capable of the laser oscillation at a wavelength of 1,550 nm; and the movable width of the movable reflection film 16 is set to 0.1 μm, thus obtaining a wavelength variable width of 52 nm from 1,550 nm.

In this case, the composition of the undoped InGaAsP waveguide layer 2 is designed such that the photoluminescence wavelength becomes 1.3 μm; in contrast, the composition of the undoped InGaAsP active layer 5 is designed such that the photoluminescence wavelength becomes 1.55 μm. Thus, within the above-described wavelength range (i.e., 1,550 nm±26 nm), the laser beam of the high output can be obtained.

That is to say, as a method for compensating the insufficient output of the surface light emitting laser, it is construed that a light amplifier for amplifying a laser beam is constituted of a separate member (for example, by the use of a substrate different from a substrate having a laser oscillator formed thereon), and then, that the light amplifier and the laser oscillator are hybrid-mounted after their fabrication.

However, the size of a beam spot of the single mode surface light emitting laser for use in optical communications is as small as 2 μm to 3 μm, and further, the width of the optical waveguide for guiding the laser beam becomes about 1.5 μm since the light beam in a high-order mode is cut. Consequently, in the case of the hybrid mounting, a mounting accuracy of 1 μm or less is needed in order to align the optical axes within a practical range. The achievement of such mounting accuracy is difficult on the current level of the mounting technique. If it was possible, an assembly cost became high.

In contrast, the optical axes can be aligned with the accuracy in the order of sub μm or less at a reduced fabrication cost by using the semiconductor fabricating technique according to the present invention.

### Second Embodiment

A light amplifier integrated surface emitting laser element in a second embodiment according to the present invention is different from that in the first embodiment in that a surface light emitting laser is formed nearer side to a substrate 100 than an optical waveguide.

Specifically, in the light amplifier integrated surface emitting laser element in the second embodiment, a semiconductor layer constituting the surface light emitting laser is grown, and then, a light amplifier and an optical waveguide are formed on a first reflection film 110.

Here, although specific materials as examples are described in parentheses or the like in the description below, the present invention is not limited to the exemplary materials.

In explaining in detail, in the light amplifier integrated surface emitting laser element in the second embodiment, on the p-type InP substrate 100 are formed a second cladding layer 113 in the laser (which is made of, for example, p-type InP) constituting the surface light emitting laser, an active layer 112 (which has, for example, an undoped InGaAsP/InGaAsP multiple quantum well structure), a first cladding layer 111 in the laser (which is made of, for example, an n-type InP layer), and the first reflection film 110 (in which, for example, n-type InP layers and n-type InGaAsP layers are alternately laminated). In a portion constituting the surface light emitting laser, a recess 120 is formed at the reverse of the substrate 100. At the bottom face of the recess 120 is formed a second reflection film 116 movably supported by beam portions in the same manner as in the first embodiment. Furthermore, a current block structure is configured by defining a high resistance region 121 with the impregnation of ions of hydrogen (H) or helium (He) in such a manner as to surround a portion immediately under the second reflection film 116, so that a current is supplied concentrically to the active layer 112 immediately under the second reflection film 116. Moreover, an anode electrode 114 for a laser oscillator is formed around the recess 120 at the lower surface of the p-type InP substrate 100.

In the above-described manner, the surface light emitting laser oscillator is constituted in the light amplifier integrated surface emitting laser element in the second embodiment.

In the light amplifier integrated surface emitting laser element in the second embodiment, an optical waveguide of a three-layer structure consisting of a second cladding layer (i.e., an n-type InP cladding layer) 103, an optical waveguide layer 102 and a first cladding layer (i.e., a p-type InP cladding layer) 101 is constituted immediately above the surface light emitting laser oscillator on the first reflection film 110 consisting of the multi-layer film, and further, a light amplifier is constituted of a three-layer structure consisting of the second cladding layer (i.e., the n-type InP cladding layer) 103, an active layer 105 and a first cladding layer (i.e., a p-type InP cladding layer) 106 and an anode electrode 117 in the light amplifier formed on the three-layer structure.

Specifically, the second cladding layer (i.e., the n-type InP cladding layer) 103 is grown on the first reflection film 110, and further, the waveguide layer (i.e., the undoped InGaAsP waveguide layer) 102 is grown on the second cladding layer 103, followed by patterning in a strip shape. Thereafter, the first cladding layer (i.e., the p-type InP cladding layer) 101 is grown by organic metal vapor phase epitaxy. Subsequently, while a portion constituting the optical waveguide remains, the first cladding layer 101 and the waveguide layer 102 are removed by etching. At the portion removed by the etching is grown the light amplifying active layer (i.e., the undoped InGaAsP active layer) 105, followed by patterning in a strip shape. Thereafter, a mesa is formed in a width of 1.5 μm, a depth of 2 μm. Current blocking layers of p-InP/n-InP/p-InP are embedded on both sides of the mesa. Thereafter, the first cladding layer 106 is grown over the entire surface. Here, the waveguide layer 102 and the light amplifying active layer 105 need be positioned such that their optical axes are aligned with each other, and it is possible to readily align the optical axes with each other with high accuracy by the use of the semiconductor fabricating technique according to the present invention.

The mesa is formed in the direction of the optical axis in such a manner as to encompass the waveguide layer 102 and the undoped InGaAsP active layer 105 therein. The anode electrode 117 of the light amplifier is formed on the mesa. Furthermore, a cathode electrode 115 shared by the light amplifier and the surface light emitting laser is formed on the second cladding layer (i.e., the n-type InP cladding layer) 103 exposed on both sides of the mesa.

Incidentally, the composition of the waveguide layer 102 made of undoped InGaAsP and the composition of the light amplifying active layer 105 made of undoped InGaAsP are set in the same manner as in the first embodiment.

Finally, a groove 118 is formed in the same manner as in the first embodiment, thereby forming a reflection mirror.

The light amplifier integrated surface emitting laser element in the second embodiment such configured as described above has the functions and effects similar to those of the light amplifier integrated surface emitting laser element in the first embodiment, and further, the light amplifier and the optical waveguide can be readily formed since the light amplifier and the optical waveguide are formed on the reflection film 110 having the multi-layer film structure whose surface can be flattened on the level of an atomic layer.

As described above, the light amplifier integrated surface emitting laser element according to the present invention comprises the surface light emitting laser having the active layer between the two reflection films facing to each other and the light amplifier including the amplifying active layer for amplifying the laser beam oscillated by the surface light emitting laser, which are provided integrally with each other on one and the same substrate, thus providing the light amplifier integrated surface emitting laser element of the high output, having the great wavelength variable width.

1. An integrated surface emitting laser element and light amplifier comprising:
a substrate.,
a surface light emitting laser portion including two reflection films facing to each other, and an active layer between the two reflection films, and
a light amplifier portion having an amplifying active layer for amplifying a laser beam produced by the surface light emitting laser portion, wherein said surface light emitting laser portion and said light amplifier portion are integrated with each other on the substrate.

2. The integrated surface emitting laser element and light amplifier according to claim 1, further comprising a reflection mirror between said surface light emitting laser portion and said light amplifier portion, wherein said light amplifier portion amplifies the laser beam reflected by said reflection mirror.

3. The integrated surface emitting laser element and light amplifier according to claim 2, further comprising an optical waveguide between said reflection mirror and said light amplifier portion, said optical waveguide being integrated with said reflection mirror and said light amplifier portion, wherein the laser beam reflected by said reflection mirror is guided by said optical waveguide to said light amplifier portion.

4. The integrated surface emitting laser element and light amplifier according to claim 3, further comprising a groove cutting said optical waveguide, wherein said reflection mirror is a cut surface of said optical waveguide in the groove.

5. The integrated surface emitting laser element and light amplifier according to claim 2, wherein said reflection mirror forms an angle of 45° with respect to each of said two reflection films.

6. The integrated surface emitting laser element and light amplifier according to claim 1, wherein a first of said two reflection films is movable to change distance between said two reflection films.

7. The integrated surface emitting laser element and light amplifier according to claim 6, wherein
a second said two reflection films is positioned between the first of said two reflection films and said substrate, and
said optical waveguide is positioned between the second of said two reflection films and said substrate.

8. The integrated surface emitting laser element according to claim 6, wherein the second of said two reflection films is positioned between said one and said optical waveguide.

9. The integrated surface emitting laser element and light amplifier according to claim 1, wherein said optical waveguide is positioned between said surface light emitting laser portion and said substrate.

10. The integrated surface emitting laser element and light amplifier according to claim 1, wherein said surface light emitting laser portion is positioned nearer to said substrate than said optical waveguide.
